(19) United States
(12) Patent Application Publication
(10) Pub. No.: US 2015/0329730 A1
(43) Pub. Date: Nov. 19, 2015

(54) UV-CURABLE DIELECTRIC INKS FOR PHOTOVOLTAIC MODULES

(71) Applicant: E I DU PONT DE NEMOURS AND COMPANY, Wilmington, DE (US)

(72) Inventors: HAIXIN YANG, DURHAM, NC (US); JOHN DONALD SUMMERS, CHAPEL HILL, NC (US); MICHAEL ZANONI BURROWS, RALEIGH, NC (US); TRISTAN WILLIAMS, CARY, NC (US)

(21) Appl. No.: 14/711,017

(22) Filed: May 13, 2015

Related U.S. Application Data
(60) Provisional application No. 61/993,079, filed on May 14, 2014.

(51) Int. Cl. C09D 11/30; H05K 3/28; C09D 11/107

(52) U.S. Cl. CPC C09D 11/30; C09D 11/107; H05K 3/285

(57) ABSTRACT

The invention relates to UV-curable dielectric ink formulations useful in digital manufacturing electric circuitry and devices. These compositions are useful in inkjet printing of electronic materials.

### FIELD OF THE INVENTION

The invention relates to UV-curable dielectric ink formulations useful in digital manufacturing electric circuitry and devices. These compositions are useful in inkjet printing of electronic materials.

### BACKGROUND OF THE INVENTION

The invention relates to dielectric formulations useful in digital manufacturing electric circuitry and devices. These compositions are useful in inkjet printing of electronic materials.

UV-curable acrylate-based formulations have been widely used in industries. Typically, they are used for coating applications and are applied by coating technologies. Polyimides have widely been used in electronic industries as dielectric materials. Polyimides are allied either by film lamination or spin-coating liquid polyimides. With the increasing demands of smaller and higher efficiency electric devices, digital printing, such as inkjet printing, and solvent-free process, such as UV-curing become appealing.

It is a technical challenge to simultaneously satisfy the requirements of electric performance, such as high resistivity, thermal stability, good adhesion to conductive layer, for example metal surface or ITO surface, processing performance, for example can be applied by inkjet, of an acrylate based dielectric material.

In this invention, epoxy acrylate or urethane acrylate monomers are mixed with other extremely viscosity aliphatic acrylates, combined with phosphine oxide photoinitiators, resulting in formulations that have good inkjetability, strong adhesion to metal or ITO surface, high resistance. The solvent-free formulations can also be cured to become solid at a very low UV-dosage.

### SUMMARY OF THE INVENTION

In an embodiment, the invention relates to a UV curable dielectric ink composition including: one or more UV curable acrylates; (b) one or more photoinitiators; and (c) one or more monomer.

In a further embodiment, the composition includes one or more components selected from the group consisting of: solvents, dyes, defoamer agents, surfactants, releasing agents, plasticizer, inorganic fillers or any combination thereof.

In a further embodiment, the one or more UV curable acrylates include one or more components selected from the group consisting of: urethane acrylate and epoxy acrylate.

### DETAILED DESCRIPTION OF INVENTION

This invention relates to UV curable dielectric ink compositions for use in thin film PV modules, wireless communication devices (antennas inside), and in-mold electronics parts. This UV curable dielectric ink composition needs to be a solvent-free, UV-curable dielectric material.

In this invention, epoxy acrylate or urethane acrylate monomers are mixed with other extremely viscosity aliphatic acrylates, combined with phosphine oxide photoinitiators, resulting in formulations that have good inkjetability, strong adhesion to metal or ITO surface, high resistance. The solvent-free formulations can also be cured to become solid at a very low UV-dosage.

In an embodiment, the dielectric material is applied on a transparent conductor oxide (TCO) layer by an inkjet process. The dielectric material is cured using a UV curing process.

### UV-Curable Monomers

Conventional acrylate and methacrylate monomers, and urethane-acrylate, urethane-methacrylate monomers, acrylate-esters and methacrylate-esters may be used in the invention. The amount of monomers ranges from 90% to 99% of the total composition weight.

Useful monomers include t-butyl acrylate and methacrylate, 1,5-pentanediol diacrylate and dimethacrylate, N,N-diethylaminoethyl acrylate and methacrylate, ethylene glycol diacrylate and dimethacrylate, 1,4-butanediol diacrylate and dimethacrylate, diethylene glycol diacrylate and dimethacrylate, hexamethylene glycol diacrylate and dimethacrylate, 1,3-propanediol diacrylate and dimethacrylate, decamethylene glycol diacrylate and dimethyacrylate, 1,4-cyclohexanediol diacrylate and dimethacrylate, 2,2-dimethylolpropane diacrylate and dimethacrylate, glycerol diacrylate and dimethacrylate, tripropylene glycol diacrylate and dimethacrylate, glycerol triacrylate and trimethacrylate, trimethylolpropane triacrylate and trimethacrylate, pentaerythritol triacrylate and trimethacrylate, polyoxyethylated trimethylolpropane triacrylate and trimethacrylate and similar compounds as disclosed in U.S. Pat. No. 3,380,831, 2,2-di(p-hydroxy-phenyl)-propane diacrylate, pentaerythritol tetraacrylate and tetramethacrylate, 2,2-di-(p-hydroxyphenyl)-propane dimethacrylate, triethylene glycol diacrylate, polyoxyethyl-2,2-di-(p-hydroxyphenyl)propane dimethacrylate, di-(3-methacryloxy-2-hydroxypropyl)ether of bisphenol-A, di-(2-methacryloxyethyl) ether of bisphenol-A, di-(3-acryloxy-2-hydroxypropyl)eiher of bisphenol-A, di-(2-acryloxyethyl)ether of bisphenol-A, di-(3-methacrloxy-2-hydroxypropyl)ether of 1,4-butanediol, triethylene glycol dimethacrylate, polyoxypropyltrimethylol propane triacrylate, butylene glycol diacrylate and dimethacrylate, 1,2,4-butanetriol triacrylate and trimethacrylate, 2,2,4-trimethyl-1,3-pentanediol diacrylate and dimethacrylate, 1-phenyl ethylene-1,2-dimethacrylate, diallyl fumarate, styrene, 1,4-benzenediol dimethacrylate, 1,4-diisopropenyl benzene, and 1,3,5-triisopropenyl benzene.

Besides monomers mentioned above, which are based on free radical polymerization, mono-, bi-, tri- tetra-functional epoxide monomers or epoxy-acrylate molecules, such as glycidyl methacrylate (GMA), which are based on cationic polymerization, are found to give rise to better performance when they co-exist with acrylate monomers and an onium salt photo-initiator. The amount of epoxide monomers ranges from 0.01% to 90% of the total weight of the ink. In an embodiment, the amount of epoxide monomers ranges from 5 to 15% of the total weight of the ink.

### Photoinitiation System

Suitable photoinitiation systems are those, which generate free radicals upon exposure to actinic light at ambient temperature. These include the substituted or unsubstituted polynuclear quinones which are compounds having two intracyclic carbon atoms in a conjugated carbocyclic ring system, e.g., 2-benzyl-2-(dimethylamino)-1-(4-morpholinophenyl)-1-butanone, 2,2-dimethoxy-2-phenylacetophenone, 9,10-anthraquinone, 2-methylanthraquinone, 2-ethylanthraquinone, 2-tert-butylanthraquinone, octamethylanthraquinone, 1,4-naphthoquinone, 9,10-phenanthrenequinone, benz (a) anthracene-7,12-dione, 2,3-naphthacene-5,12-diene, 2-methyl-1,4-naphthoquinone, 1,4-dimethylanthraquinone, 2,3-dimethylanthraquinone, 2-phenylanthraquinone, 2,3-diphenylanthraquinone, retenequinone, 7,8,9,10-tetrahydronaphthracene-5,12-diene, and 1,2,3,4-tetrahydrobenz(a)anthracene-7,12-dione. Other photoinitiators which are also useful, even though some may be thermally active at temperatures as low as 85 C, are described in U.S. Pat. No. 2,760,863 and include vicinal ketaldonyl alcohols such as benzoin, pivaloin, acyloin ethers, e.g., benzoin methyl and ethyl ethers; β-hydrocarbon-substituted aromatic acyloins, including α-methylbenzoin, α-allylbenzoin and α-phenylbenzoin, thioxanthone and/or thioxanthone derivatives and the appropriate hydrogen donors. Photoreducible dyes and reducing agents disclosed in U.S. Pat. Nos. 2,850,445, 2,875,047, 3,097,096, 3,074,974, 3,097,097, and 3,145,104, as well as dyes of the phenazine, oxazine, and quinone classes, Michler's ketone, benzophenone, 2,4,5-triphenylimidazolyl dimers with hydrogen donors including leuco dyes and mixtures thereof as described in U.S. Pat. Nos. 3,427,161, 3,479,185, and 3,549,367 can be used as initiators. Also useful with photoinitiators and photoinhibitors are sensitizers disclosed in U.S. Pat. No. 4,162,162. The photoinitiator or photoinitiator system is present in 0.05 to 20% of the total composition weight. In an embodiment, the amount of the photoinitiator or photoinitiator system ranges from 1 to 5% of the total weight of the ink.

### Dyes

In an embodiment, the formulations may also optionally contain dyes. Dyes are those, which can help absorb 532 nm green laser to facilitate melt or remove UV-cured formulations. Preferred dyes are those with maximum absorption at or around 532 nm. These include Phenol Red, Acid Red One, Diiodofluorescein, EMODIN, Eosin B, Erythrosin yellowish blend, NEW FUCHSIN, Safranine O and Phthalocyanine Green.

### Other Additives

Formulations can also contain other additives, such as plasticizers, releasing agents, deformers, carbon fillers, surfactants, nano-size silica and nano-size metal oxide powders. Formulations can also contain solvents.

In an embodiment, the invention relates to a method of making a device including the UV curable dielectric ink composition. The method includes applying the composition on a TOO layer on a substrate using an inkjet process; and curing the composition using UV curing. The UV curing dosage may be <100 mj/cm2. The contact angle on stainless steel or silver/nickel alloy or ITO surface may be <20 degree. The surface tension of the compositions may range from 20 to mN/m. The adhesion of cured compositions on the above surface may be >4.5B by ASTM D3359 method B. The resistivity of cured composition film may be >10.000 Ohm at 10 microns thickness. The thermal stability, defined by resistance change after heated at 2600 for 5 min, is no change in resistance. The glass transition temperature of the cured composition may be >800 or no glass transition temperature. Other components may include black or blue or green colorants, deformers, surfactants. There is no solvent in any composition, i.e. solvent-free. Curing methods include High pressure mercury lamps for <385 nm and LED UV lamps for 395 nm and 405 nm. The printing or deposition methods include inkjet, aerosol printing and others. Final devices that use the compositions include thin film PV modules, wireless communication devices (antennas inside), and in-mold electronics parts.

### EXAMPLES

Formulations include UV-curable acrylate monomers and photo- initiators. Formulations are liquid. After UV-curing, formulations become solid. Resulting solid may or may not show a glass transition temperature, i.e. resulting solid can be thermoplastic or thermosetting. Formulations can also contain solvents, dyes, deformer agents, surfactants, releasing agents, plasticizers and inorganic fillers. Formulations are described in the following examples.

### Materials

All materials were obtained from Sartomer USA, LLC unless specified a resource below. Esacure KT064 and Esacure TZT were obtained from Lamberts USA, Inc., Irgacure 651, Irgacure 819 and Iragcure 250 from BASF Corporation, FirstCure EDAB from Albemarle Corporation, Quantacure ITX from Great Lakes Chemicals, Inc., phthalocyanine green from Penn Color and BYK UV3505 from BYK-Chemie GmbH. IDS-PR-604 was obtained from Intergrated Digital System GnbH, and LWU7400KK from Nazdar Corporation. Glycidyl methacrylate, 3-(trimethoxysilyl)propyl acrylate, tributyl citrate and Phenol Red were obtained from Sigma-Aldrich.

### Sample Preparation

All ingredients formulations were mixture at room temperature until all ingredients were dissolved. Samples were filtered through a 0.45-micron nylon or polypropylene filter from Millipore Corporation before inkjet printing.

### Properties of Formulations

Viscosity: 2-500 cP at 25 C, 2-50 cP at 40 C and 1-15 cP at 60 C. Preferred viscosity dependents on deposition method. For inkjet, preferred viscosity is 8-20 cP at jetting temperature.

Surface tension: 15-60 mN/m at 25 C; preferred range is 20-40 and most preferred 24-30.

Contact Angle: 5-60 degree, preferred 8-40, most preferred 10-15.

UV-curing energy: 5 mj/cm2 to 1000 mj/cm2. Preferred 20-500 and most preferred 50-200 by LED UV light source at 365 nm or 395 nm. Nitrogen atmosphere may or may not be needed for UV-curing. Preferred is no nitrogen, i.e. curing in air. Our formulations can be cured in air.

Resistance of UV-cured films at 10 microns thick >10,000 Ohm. After being heated at 260 C for 5 min, the cured formulation does not change resistance.

Glass transition temperature of formulations after UV-curing and after a conductive layer is deposited on top of a formulation is above 80 C or no glass transition temperature.

### Deposition of Formulations

All formulations can be deposited or applied onto a substrate, such as glass, ceramic, plastic, transparent conductive oxides. Deposition methods include inkjet, scree-printing, aerosol-printing (Optomec method), smart-pen printing (nScrypt method), flexo printing, gravure printing, pad printing and general coating methods.

| | | Examples | | | | | | | | | |
|---|---|---|---|---|---|---|---|---|---|---|---|
| | Description | 1 | 2 | 3 | 4 | 5 | 6 | 7 | 8 | 9 | 10 |
| SR506A | low shrinkage | 20 | 20 | 20 | 20 | 20 | 20 | 20 | 20 | 20 | 20 |
| | diacrylate | | | | | | | | | | |
| SR531 | high Tg | 10 | 10 | 10 | 10 | 10 | 10 | 10 | 10 | 10 | 10 |
| | monoacrylate | | | | | | | | | | |
| SR508IJ | low viscosity | 20 | 20 | 20 | 20 | 20 | 20 | 20 | 20 | 20 | 20 |
| | diacrylate | | | | | | | | | | |
| CN386US | reactive co- | 10 | 10 | 10 | 10 | 10 | 10 | 10 | 10 | 12 | 12 |
| | initiator | | | | | | | | | | |
| CN2279 | polyester | 11 | 11 | 11 | 11 | 11 | 11 | 11 | 11 | 12 | 10 |
| | acrylate for | | | | | | | | | | |
| | toughness | | | | | | | | | | |
| CN968 | hexafunctional | 5 | 5 | 5 | 5 | 5 | 5 | 5 | 5 | 5 | 5 |
| | urethane | | | | | | | | | | |
| | acrylate | | | | | | | | | | |
| SR454H | triacrylate | 5 | 5 | 5 | 5 | 5 | 5 | 5 | 5 | 7 | 7 |
| CN132 | triacrylate | 10 | 10 | 10 | 10 | 10 | 10 | 10 | 10 | 10 | 10 |
| BYK | surfactant | 0.5 | 0.5 | 0.5 | 0.5 | 0.5 | 0.5 | 0.5 | 0.5 | 0.5 | 0.5 |
| UV3505 | | | | | | | | | | | |
| Esacure | free radical PI | 6 | | 6 | | 3 | | 3 | | | |
| KTO46 | | | | | | | | | | | |
| Esacure | free radical PI | 2 | | 2 | | 1 | | 1 | | | |
| TZT | | | | | | | | | | | |
| Irgacure | free radical PI | | 3 | | 3 | | 1.5 | | 1.5 | 0.5 | 0.5 |
| 651 | | | | | | | | | | | |
| FirstCure | free radical PI | | 2 | | 2 | | 1 | | 1 | 0.25 | 0.25 |
| EDAB | | | | | | | | | | | |
| Quantacure | free radical PI | | 2 | | 2 | | 1 | | 1 | 0.25 | 0.25 |
| ITX | | | | | | | | | | | |
| TMSiPA | releasing agent | | | 1 | 1 | | | 1 | 1 | 1 | 1 |
| Phenol Red | dye | | | 0.1 | 0.1 | | | 0.1 | 0.5 | 0.5 | 0.5 |
| Tributyl | plasticizer | | | 0.5 | 0.5 | | | 0.5 | 0.5 | 0.5 | 0.5 |
| citrate | | | | | | | | | | | |
| GMA | epoxy | | | | | | | | | | 2 |
| Irgacure | cationic PI | | | | | | | | | | 0.5 |
| 250 | | | | | | | | | | | |

Examples

| | | 11 | 12 | 13 | 14 | 15 |
|---|---|---|---|---|---|---|
| SR531 | high Tg monoacrylate | 10 | 10 | 15 | 20 | 15 |
| CN133 | triacrylate | 15 | | | | 10 |
| CN132 | low viscosity CN133 | | 15 | 10 | 10 | |
| CN2279 | polyester acrylate for | 10 | 10 | 12.5 | 7.5 | 12.5 |
| | toughness | | | | | |
| CN968 | hexafunctional | 5 | 5 | 2.5 | 2.5 | 2.5 |
| | urethane acrylate | | | | | |
| CN386US | reactive co-initiator | 4 | 4 | 4 | 4 | 4 |
| Esacure KT046 | free radical PI | 3 | 3 | 3 | 3 | 3 |
| Esacure TZT | free radical PI | 1 | 1 | 1 | 1 | 1 |
| Phthalocyanine | dye | 0.1 | 0.1 | 0.1 | 0.1 | 0.1 |
| Green | | | | | | |

| Ingredient | description | 16 | 17 | 18 | 19 |
|---|---|---|---|---|---|
| CN981 | aliphatic polyester urethane | 20.0 | 20.0 | 20.0 | 20.0 |
| | diacrylate | | | | |
| SR420 | monoacrylate | 22.5 | 22.0 | 22.0 | 22.0 |
| CD595 | acrylate | 20.0 | 20.0 | 20.0 | 20.0 |
| SR295 | Pentaerythritol tetraacrylate | 8.0 | 8.0 | 8.0 | 8.0 |
| SR306F | tripropylene glycol diacrylate | 23.0 | 23.0 | 22.0 | 21.5 |
| IDS-PR-604 | UV-curable adhesion promoter | | | 3.0 | 3.0 |
| LWU7400KK | UV-curable black ink | 0.5 | 1.0 | 0.5 | 1.0 |
| Irgacure | BAPO/TPO Photoinitiator (PI) | 4.0 | 4.0 | 3.0 | 3.0 |
| 819 | | | | | |
| Irgacure | benzyldimethyl ketal, co-PI | 2.0 | 2.0 | 1.5 | 1.5 |
| 651 | | | | | |

PI = photo initiator
GMA: Glycidyl methacrylate.
TMSiPA: 3-(trimethoxysilyl)propyl acrylate

What is claimed is:

1. A UV curable dielectric ink composition comprising:
(a) one or more UV curable acrylates;
(b) one or more photoinitiators; and
(c) one or more monomer.

2. The composition of claim 1, further comprising one or more components selected from the group consisting of: solvents, dyes, defoamer agents, surfactants, releasing agents, plasticizer, inorganic fillers or any combination thereof.

3. The composition of claim 1, wherein the one or more UV curable acrylates comprise one or more components selected from the group consisting of: urethane acrylate and epoxy acrylate.

4. The composition of claim 2, wherein the urethane acrylate is selected from the group consisting of: aliphatic polyester and urethane diacrylate.

5. The composition of claim 2, wherein the epoxy acrylate comprises glycidyl methacrylate (GMA).

6. The composition of claim 1, wherein the one or more photoinitiators comprise one or more components selected from the group consisting of: phosphine oxide, Norris type I photoinitator, and Norris type II photoinitiator.

7. The composition of claim 1, wherein the monomer comprises a low viscosity acrylate.

8. The composition of claim 1, wherein the UV curable acrylates are 60-98 wt %, based on the total weight of the composition.

9. The composition of claim 1, wherein the photoinitiators are 0.05-20 wt %, based on the total weight of the composition.

10. The composition of claim 1, further comprising one or more component selected from the group consisting of: solvents, dyes, defoamer agents, surfactants, releasing agents, plasticizer, and inorganic fillers.

11. A method of making a device comprising the UV curable dielectric ink composition of claim 1, comprising:
(a) applying the composition on a TCO layer on a substrate using an inkjet process; and
(b) curing the composition using UV curing.

12. The method of claim 10, wherein the substrate is selected from the group consisting of: glass, ceramic, plastic, and transparent conductive oxides.

13. A device comprising a dielectric, wherein, prior to curing, the dielectric comprises the composition of claim 1.

14. The device of claim 12, wherein the device is selected from the group consisting of: thin film PV modules, wireless communication devices, antennas, and in-mold electronics.
